(19) United States
(12) Patent Application Publication
(10) Pub. No.: US 2012/0037403 A1
(43) Pub. Date: Feb. 16, 2012

(54) Method for Electrically Conductively Connecting Conductor Tracks in Conductor Carriers and System Comprising such Conductor Carriers

(75) Inventor: Uwe Liskow, Asperg (DE)

(73) Assignee: Robert Bosch GmbH, Stuttgart (DE)

(21) Appl. No.: 13/206,491

(22) Filed: Aug. 9, 2011

(30) Foreign Application Priority Data
Aug. 10, 2010 (DE) 10 2010 039 146.8

(51) Int. Cl. H05K 1/02; H01R 43/00

(52) U.S. Cl. 174/251; 29/825

(57) ABSTRACT

A method for electrically conductively connecting conductor tracks in conductor carriers, preferably printed circuit boards or conductor foils is disclosed. A first and second conductor carrier are provided, into which a respective conductor track is embedded, which are exposed at a contact region. For the purpose of fusing the material of the conductor tracks, said material is subjected to punctiform heating via the in the opposite direction to the exposed contact region of the first conductor carrier faces. A connection location of conductor tracks which can be produced cost-effectively and is well protected is provided as a result.

This application claims priority under 35 U.S.C. §119 to German patent application no. DE 10 2010 039 146.8, filed Aug. 10, 2010 in Germany, the disclosure of which is incorporated herein by reference in its entirety.

### BACKGROUND

DE 10 2004 061 818 A1 discloses a control module, in particular for a transmission of a motor vehicle. The control module comprises a housing, in the interior of which an electronic circuit part is arranged. Furthermore, a flexible conductor foil for electrically connecting the electronic circuit part to electrical components arranged outside the housing interior is provided. The electronic circuit part is linked to the flexible conductor foil via bonding wires.

Furthermore, DE 102 61 019 A1 discloses a connection arrangement for non-releasable laser welding connection between a flat lead frame and a pin, and also a method for producing such a non-releasable welding connection.

### SUMMARY

The method according to the disclosure for electrically conductively connecting conductor tracks in conductor carriers comprises the following steps: providing a first and second conductor carrier, into which a respective conductor track is embedded, which is exposed at a contact region. The conductor carriers are preferably printed circuit boards or conductor foils. The term “conductor carrier” in the context of this disclosure therefore encompasses a printed circuit board (PCB), a circuit board, a flexible conductor foil and also a flexible printed circuit board (FCB=Flexible Printed Circuit), also designated as flexible circuit board or flexible circuit. “Embedded” preferably means that the periphery of the conductor track material is surrounded in closed fashion by material of the conductor carrier, except at selected contact locations for producing electrical contact. Furthermore, the method comprises punctiform heating of the material of the conductor tracks via a side of the first conductor carrier which faces in the opposite direction to the exposed contact region. Preferably, laser welding is employed in this case, wherein the wording “via a side” specifies that the heat source is introduced from this side (the top side in FIG. 1), in the case of laser welding the laser beam being radiated in from this side. This step of punctiform heating leads to the partial fusion of the material of the conductor tracks. This method and the system, which is likewise defined as an independent claim, have the advantage over the prior art that it can be realized more cost-effectively because the production process can be automated more easily. Furthermore, bonding wire connections in the art have to be enclosed and/or encapsulated in gel and are therefore not available for further contact-connection, whereas according to the disclosure a transmission control unit can be made available as a pretested and encapsulated unit. A further advantage of the connection according to the disclosure can be seen in its high quality that exceeds the connection quality resulting from bonding, soldering or the like. Furthermore, the inventor of the present disclosure has discovered that welding or laser welding is technically difficult to implement if both contact partners (conductors) do not have approximately the same material thickness. In the case of a thick lead frame contact or a round pin, a connection to a thin conductor track of a module printed circuit board is difficult to produce. By contrast, the connection described here represents a possibility for enabling comparable contact materials to be connected in a very small structural space. Moreover, the connection presented here is well protected, because the printed circuit boards can lie one directly on another and the fused contact region of the conductor tracks is therefore not externally accessible to operating media (transmission oil, swarf).

Advantageous developments and improvements of the method and system defined in the independent claims are specified by the measures presented in the dependent claims.

In accordance with one exemplary embodiment, the method furthermore comprises the step of forming a cutout, to be precise in the first conductor carrier on the side facing in the opposite direction to the exposed contact region, wherein the step of punctiform heating is effected via the cutout. As a result of a cutout being provided, less or none of the conductor carrier material has to be melted/burned away before the laser beam impinges on the conductor track material. The method is therefore more energy-efficient.

In accordance with one exemplary embodiment of the method, the punctiform heating of the material of the conductor track involves laser welding. This enables said method to be implemented very precisely and in a well-controllable manner.

In accordance with a further exemplary embodiment of the method, before the heating, a thin layer of the conductor carrier material is situated between the cutout and the conductor track of the first conductor carrier, said layer being removed by the heating. This has the advantage that the material of the conductor track in the contact region, facing toward the cutout, remains protected, for example against dust, dirt or oil, until the actual connecting or fusing step.

In accordance with an alternative exemplary embodiment, a method is provided wherein through the cutout, the conductor track of the first conductor carrier is exposed on the side which faces in the opposite direction to the exposed contact region. This has the advantage that the method is somewhat more cost-effective, because it is not necessary to ensure that a thin material layer remains behind and the thin material layer does not have to be melted away before the printed circuit board material is fused together.

In accordance with a further exemplary embodiment, after the fusion of the conductor tracks, the cutout is closed with a protective material. This protective material is preferably in the form of a potting compound, preferably composed of thermoplastic material. However, other protective materials are also conceivable, such as, for example, a cover or a stopper, preferably composed of plastic.

Moreover, the cutout can be coated with a lacquer coating. This has the advantage that the connection location is protected, which is particularly advantageous in the case of use in a transmission control unit, because the latter can be surrounded by transmission oil (and possibly abrasion swarf) during operation.

In accordance with a further exemplary embodiment, in the method described here, a welding depth and/or melting regulation is carried out during the punctiform heating. This has the advantage that the connection process is process-regulatable, which makes the quality of the connection location optimizable.

In accordance with a further exemplary embodiment, a system comprising such a connection location is provided, wherein the first conductor carrier together with the electronic components situated thereon is enclosed by a protective enclosure. Preferably, the protective enclosure together with the second conductor carrier completely surrounds the first conductor carrier. Said protective enclosure is preferably in the form of a potting compound or injection-molded encapsulation, preferably composed of thermoplastic material. However, other protective enclosures are also conceivable, such as, for example, a cover or a hood, preferably composed of plastic. Furthermore, a lacquer coating can be applied. This protects the transmission control unit against operating media.

### BRIEF DESCRIPTION OF THE DRAWINGS

Exemplary embodiments of the disclosure are illustrated in the drawings and explained in greater detail in the following description.

In the figures:

FIG. 1 shows the system according to the disclosure with the conductor tracks to be connected in accordance with one exemplary embodiment of the disclosure,

FIG. 2a shows a further exemplary embodiment of the first printed circuit board in a side view illustrated sectionally along a conductor track,

FIG. 2b shows the printed circuit board from FIG. 2a in a plan view,

FIG. 3a shows the module printed circuit board with the transmission control unit arranged thereon in a plan view,

FIG. 3b shows a side view of the system illustrated in FIG. 3a, and

FIG. 4 shows the transmission control unit mounted onto the module printed circuit board in a temporal sectional illustration.

### DETAILED DESCRIPTION

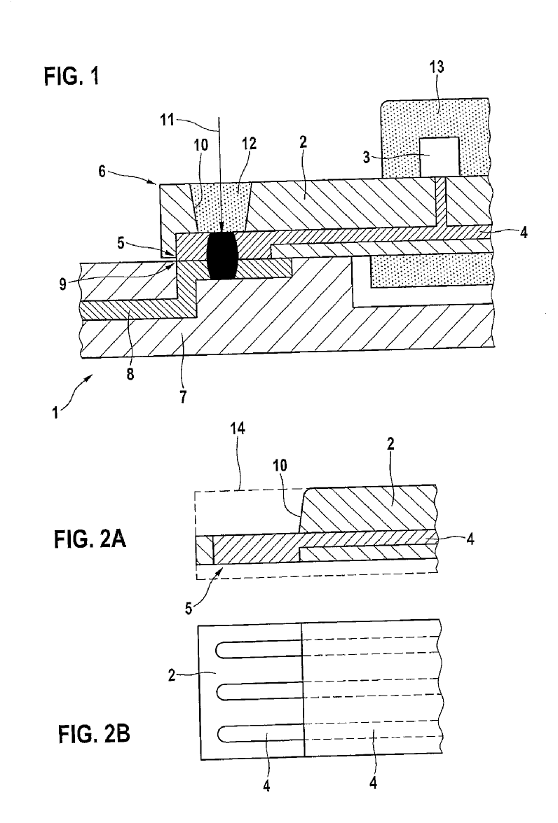

FIG. 1 shows the system according to the disclosure with the conductor tracks to be connected in accordance with one exemplary embodiment of the disclosure. The system 1 comprises a first printed circuit board 2 as first conductor carrier, which is preferably the printed circuit board of a transmission control unit. Said printed circuit board 2 is preferably the direct circuit carrier for the entire electronics of a transmission control unit. FIG. 1 illustrates an electronic component 3 of said electronics. The printed circuit board 2 consists of electrically insulating material, for example fiber-reinforced plastic, glass fiber mats impregnated in epoxy resin, pertinax, etc. There is embedded into the printed circuit board 2 at least one conductor track 4, but preferably a multiplicity of conductor tracks 4. In this case, the conductor tracks 4 are embedded in such a way that they are surrounded completely by the material of the printed circuit board 2 over a large part of their length in a cross section perpendicular to their longitudinal directions. In a contact region 5, the conductor track 4 is exposed, that is to say externally accessible and bare. This is realized in the present exemplary embodiment by the material of the printed circuit board being made thicker in the contact region 5, such that the material of the conductor track 4 is flush with the material of the printed circuit board 2. Electrically conductive material, for example copper, is appropriate as material of the conductor track 4. This arrangement of printed circuit board 2 with conductor tracks 4 embedded therein and the electronics 3 carried by the printed circuit board 2 substantially forms the transmission control unit 6. In this case, the contact regions 5 form the electrical connections of the electronic components 3 toward the outside, that is to say to electrical components outside the transmission control unit 6. For this purpose, one or a plurality of ends of the conductor track 4 which are remote from the contact region 5 is or are connected to one or a plurality of components 3. That is to say that the conductor track 4 runs within the printed circuit board 2 as far as the electrical component 3 and is connected to the latter there. For this purpose, the conductor track 4 is also exposed at these connection locations, in addition to the contact region 5. The system 1 furthermore comprises a module printed circuit board 7 (also designated as “E-module AVT” in the art) as second conductor carrier, which is likewise produced from electrically insulating material (for example one of the materials mentioned above). Conductor tracks 8 produced from electrically conductive material, for example copper, run within the module printed circuit board 7. One or a plurality of conductor tracks 8 or conductor track layers can be provided. These are embedded into the module printed circuit board 7 in such a way that they are surrounded completely by the material of the module printed circuit board 7 over the majority of their length in cross section perpendicular to their longitudinal direction. The conductor tracks 8 are exposed in a contact region 9, which is achieved in this exemplary embodiment by virtue of the fact that, at the contact region 9, the conductor track 8 is led to the outer side of the printed circuit board 7, where it runs flush with the outer side of the printed circuit board 7. For the purpose of connecting the contact region 5 to the contact region 9, laser welding is preferably provided, but some other method using some other punctiform heat source or a method for the punctiform heating of the material of the conductor tracks 4, 8 is also suitable. For this purpose, a cutout 10 is formed in the first printed circuit board 2. In the exemplary embodiment illustrated in FIG. 1, the cutout 10 extends from the top side of the printed circuit board 2 as far as the conductor track 4 approximately centrally with respect to the contact region 5 (relative to the horizontal in FIG. 1), wherein the cutout 10 has a diameter that is smaller than the contact region 5 and large enough to be able to introduce a laser beam for the laser welding method. In this case, the top side of the printed circuit board 2 is the outer side facing in the opposite direction to the contact region 5. The cutout 10 is therefore a preferably round opening above the conductor track location to be welded. In the exemplary embodiment illustrated in FIG. 1, the cutout 10 is removed by milling. This milling can be effected locally as illustrated in this figure or else, as illustrated in FIGS. 2a, 2b, can also be effected areally. As an alternative thereto, the printed circuit board material can be omitted in the region of the cutout 10 from the start during the printed circuit board production process. For this purpose, for forming the cutout 10, where the printed circuit board contact points of the printed circuit board 2 which are to be connected to the module printed circuit board 7 are situated, the printed circuit board material is removed or omitted. Consequently, the external contact (contact region 5) of the printed circuit board 2 that is to be welded is situated in metallically bare fashion on the contact side (the underside of the printed circuit board 2 in FIG. 1) and likewise in metallically bare fashion on the rear side of the contact side (the top side of the conductor track 4 in FIG. 1). As an alternative thereto, the cutout 10 can also be formed in such a way that a thin material layer of printed circuit board material (a thin skin) is present between the cutout 10 and the conductor track 4. Said thin material layer is then burned way or melted away during later laser welding by means of the laser beam and the heat produced in the process. For the purpose of fusing the conductor tracks 4 and 8 in their contact regions 5 and 9, the printed circuit boards 2 and 7 are placed with their top side and underside one on top of another, such that the contact regions 5 and 9 touch one another. In relation to the application in the case of a transmission control module, the finished tested transmission control unit 6 is placed onto the module printed circuit board 7 and positioned. Afterward, a laser beam, indicated by an arrow and provided with the reference symbol 11, is applied via the top side of the printed circuit board 2 onto the conductor track 4 (or onto the thin skin if present), such that heat develops in the contact region 5 and 9 in such a way that the material of the conductor tracks 4 and 8 is fused together at least in sections in their contact regions 5 and 9, such that an electrically conductive connection arises between the conductor tracks 4 and 8. A welding depth and/or melting regulation takes place during the laser welding. After the laser welding, the cutout 10 can be closed with potting compound 12 for protection against operating media, such as, for example, transmission oil with metal swarf. Moreover, the electronics with the components 3 can likewise be surrounded by an enclosure 13, which is formed by the electronics being encapsulated by casting or injection molding. For the purpose of closing the cutout 10, the region around the contact location can be protected by an impermeable swarf protection cover, a lacquer coating, the potting compound already mentioned, or an injection-molded encapsulation. This protection can be effected partially, i.e. directly only at the bare welding connection, the region around this location, or, alternatively, the entire transmission control unit 6 mounted on the module printed circuit board 7 could be encapsulated by casting (illustrated in FIG. 4).

FIG. 2a shows a further exemplary embodiment of the first printed circuit board 2 in a side view illustrated sectionally along a conductor track 4. The printed circuit board 2 differs from the printed circuit board illustrated in FIG. 1 in that the cutout 10 is formed by milling the material of the printed circuit board 2 over the entire width of the printed circuit board 2 in the region of the contact region 5. In this case, the lines 14 illustrated in a dashed manner in FIG. 2a show the original outer contour of the printed circuit board 2. A printed circuit board 2 in which the conductor track 4 is already uncovered in the contact region 5 after production was described in connection with FIG. 1. However, it is likewise possible, as illustrated in FIG. 2a, for the conductor track 4 to be exposed only by the milling of the underside of the printed circuit board 2. As can be discerned in FIG. 2a, the dashed line 14 shows the original contour on the underside of the printed circuit board 2. The milling gives rise to a step on the underside of the outer printed circuit board of the transmission control unit.

FIG. 2b shows the printed circuit board from FIG. 2a in a plan view. The exposed conductor tracks 4 can be discerned in the left-hand half of FIG. 2b, whereas said conductor tracks are illustrated in a dashed manner in the right-hand half of FIG. 2b because they are concealed by the material of the printed circuit board material.

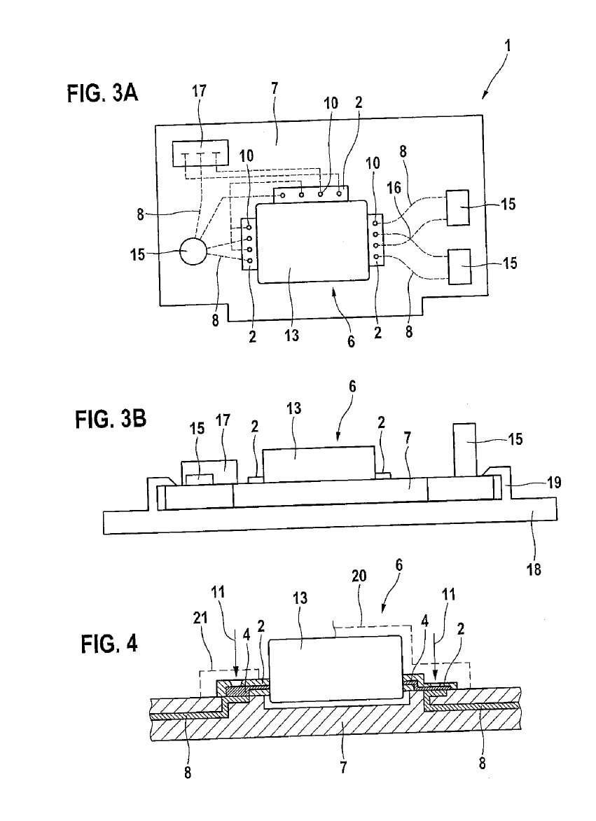

FIG. 3a shows the module printed circuit board 7 with the transmission control unit 6 arranged thereon, in a plan view. The transmission control unit 6 is connected to the module printed circuit board 7 in the manner described above. The conductor tracks 8 run within the module printed circuit board 7 and produce the connection to sensors 15, which are likewise arranged on the module printed circuit board 7 and are electrically connected to another, likewise exposed, end of a conductor track 8. Crossover points 16 can also be realized by the conductor tracks 8 being embodied in a multilayered fashion. For this purpose, the conductor tracks 8 are embedded in different planes within the module printed circuit board 7, such that the insulating module printed circuit board material is situated between the conductor tracks 8. Moreover, a connector 17 is furthermore provided, which is likewise connected to the ends of conductor tracks 8 and via which the system 1 can be connected to external electronic components.

FIG. 3b shows a side view of the system 1 illustrated in FIG. 3a. In contrast to FIG. 3a, however, a carrier plate 18 of the transmission control module is furthermore provided. Said carrier plate 18 has claws 19 which engage around and fix the module printed circuit board 7 in the thickness direction (vertical in FIG. 3b).

FIG. 4 shows the transmission control unit 6 mounted onto the module printed circuit board 7 in a lateral sectional illustration. In this case, the different possibilities for covering the contact regions or the entire transmission control unit 6 are illustrated in FIG. 4. The right-hand half of FIG. 4 illustrates, by means of the dashed line 20, a protective enclosure which spans the entire transmission control unit 6 and which is formed by the entire transmission control unit 6 being potted or encapsulated by injection molding. Said protective enclosure serves, as already described, for protection against operating media. In the left-hand half of FIG. 4, the contact regions are only partially covered, as is illustrated by the dashed line 21. For this purpose, only the contact regions are encapsulated by casting or injection molding after the laser welding.

In a modification relative to the exemplary embodiment described above, wherein the first printed circuit board 2 is the direct circuit carrier for the entire electronics of the transmission control unit, in accordance with a further exemplary embodiment the printed circuit board 2 is only an interface strip within the transmission control unit encapsulated by injection molding or housed in some other way. For this purpose, by way of example, the printed circuit board 2 can serve as an interface printed circuit board, which is mechanically connected to a hybrid ceramic circuit carrier, wherein the conductor tracks of the interface printed circuit board and are connected to corresponding electrical contacts or conductor tracks of the hybrid ceramic circuit carrier.

The connection technique described can generally be used for the connection of two printed circuit boards, not just for the connection of a transmission control unit to a module printed circuit board as explained in greater detail in the exemplary embodiment. It is also possible to connect two sub-module printed circuit boards to be connected or printed circuit board sensors to the module printed circuit board.

The disclosure is likewise suited to the welding of flexible conductor foils or flexible printed circuit boards. Flexible printed circuit boards are thin flexible printed circuit boards, for example based on polyimide films, into which conductor tracks are embedded. The flexible connections constructed in this way are suitable for continuous stress and the connection of elements that are moved relative to one another. When welding such flexible printed circuit boards, a region to be welded of a flexible printed circuit board is exposed, that is to say that at least the covering layer of the flexible printed circuit board is milled or etched away or removed in some other way and the flexible printed circuit board is then welded by the bare side onto the exposed conductor track of a printed circuit board (e.g. contact region 9 of the conductor track 8). The laser beam either passes through the upper covering film or the latter is exposed in the region of the planned welding point or an opening is already formed in the covering film during the production of the flexible printed circuit board.

It should be pointed out that terms such as “one” or “a” do not preclude a plurality. Furthermore, it should be pointed out that features which have been described with reference to one of the above further developments can also be used in combination with other features of other further developments described above. Reference symbols in the claims should not be regarded as a restriction.

What is claimed is:

1. A method for electrically conductively connecting conductor tracks in conductor carriers, comprising:
providing a first and second conductor carrier, into which a respective conductor track is embedded, which is exposed at a contact region;
punctiform heating of the material of the conductor tracks via a side of the first conductor carrier which faces in the opposite direction to the exposed contact region, and
at least partial fusion of the material of the conductor tracks.

2. The method according to claim 1, further comprising:
forming a cutout in the first conductor carrier on the side facing in the opposite direction to the exposed contact region, wherein the step of punctiform heating is effected via the cutout.

3. The method according to claim 1, wherein the punctiform heating of the material of the conductor tracks involves laser welding.

4. The method according to claim 2, wherein, before the heating, locating a thin layer of the conductor carrier material between the cutout and the conductor track of the first conductor carrier, said layer being at least partially removed by the heating.

5. The method according to claim 2, wherein, through the cutout, the conductor track of the first conductor carrier is exposed on the side which faces in the opposite direction to the exposed contact region.

6. The method according to claim 2, wherein, after the fusion of the conductor tracks, the cutout is closed with a protective material.

7. A system, comprising:
a first and second conductor carrier into which a respective conductor track is embedded, which is exposed at a contact region; and
a cutout in the material of the first conductor carrier on the side facing in the opposite direction to the exposed contact region,
wherein the conductor tracks of the first and second conductor carriers are at least partially fused at their contact regions.

8. The system according to claim 7, wherein the cutout is at least partially filled with a protective material.

9. The system according to claim 7, wherein the system is a transmission control module.

10. The system according to claim 7, wherein the first conductor carrier together with electronic components situated thereon is enclosed by a protective enclosure.
